(19) United States
(12) Patent Application Publication
(10) Pub. No.: US 2011/0057257 A1
(43) Pub. Date: Mar. 10, 2011

(54) Semiconductor device and method for manufacturing the same

(75) Inventors: Ki Yeol Park, Suwon-si (KR); Jung Hee Lee, Daegu-si (KR); Jong Bong Ha, Daegu-si (KR); Young Hwan Park, Seoul (KR); Woo Chul Jeon, Suwon-si (KR)

(73) Assignee: SAMSUNG ELECTRO-MECHANICS CO., LTD., Suwon (KR)

(21) Appl. No.: 12/654,942

(22) Filed: Jan. 8, 2010

(30) Foreign Application Priority Data
Sep. 8, 2009 (KR) 10-2009-0084593

(51) Int. Cl. H01L 29/78; H01L 21/336

(52) U.S. Cl. 257/330; 438/270; 257/194; 257/E29.262; 257/E21.41

(57) ABSTRACT

The present invention provides a semiconductor device including: a base substrate; a semiconductor layer which is disposed on the base substrate and has a recess structure formed thereon; a gate structure covering the recess structure; a source electrode and a drain electrode which are disposed to be spaced apart from each other with respect to the gate structure interposed therebetween, on the semiconductor layer, wherein the semiconductor layer having an upper layer whose thickness is increased toward a first direction facing the drain electrode from the gate structure.

### CROSS-REFERENCE TO RELATED APPLICATIONS

This application claims the benefit of Korean Patent Application No. 10-2009-0084593 field with the Korea Intellectual Property Office on Sep. 8, 2009, the disclosure of which is incorporated herein by reference.

### BACKGROUND OF THE INVENTION

1. Field of the Invention

The present invention relates to a semiconductor device; and, more particularly, to a semiconductor device with an N-FET structure, and a method for manufacturing the same.

2. Description of the Related Art

In general, III-nitride-based semiconductor which includes III-elements such as Ga, Al, In, and so on, and N is characterized by a wide energy band gap, high electron mobility and saturation electron speed, and high thermal-chemical stability. Such an Nitride-based Field Effect Transistor (N-FET) is manufactured based on a semiconductor material with a wide energy band gap, e.g., materials of GaN, AlGaN, InGaN, and AlINGaN.

A typical N-FET has a High Electron Mobility Transistor (HEMT) structure. For example, a semiconductor device with the HMET structure is provided with a base substrate, a nitride-based semiconductor layer formed on the base substrate, source and drain electrodes disposed on the semiconductor layer, and a gate electrode disposed on the semiconductor layer between the source and drain electrodes. A 2-Dimensional Electron Gas (2DEG) used as a current path may be generated within the semiconductor layer of the semiconductor device. However, the N-FET having the same structure has problems in that an electric field is concentrated on the gate and drain electrodes, and thus errors occur in transistor operation. In particular, since the semiconductor device with the HEMT structure is required to be operated at a high voltage, a high electric field concentrated on the gate and drain electrodes causes a reduction in device's characteristics.

### SUMMARY OF THE INVENTION

The present invention has been proposed in order to overcome the above-described problems and it is, therefore, an object of the present invention to provide a semiconductor device which has an HEMT structure for improving device's characteristics, and a method for manufacturing the same.

Moreover, another object of the present invention is to provide a semiconductor device which has an HEMT structure capable of high-voltage operation, and a method for manufacturing the same.

Furthermore, another object of the present invention is to provide a semiconductor device which has an HEMT structure for preventing an electric field from being concentrated on gate and drain electrodes, and a method for manufacturing the same.

In accordance with one aspect of the present invention to achieve the object, there is provided a semiconductor device including: a base substrate; a semiconductor layer which is disposed on the base substrate and has a recess structure formed thereon; a gate structure covering the recess structure; a source electrode and a drain electrode which are disposed to be spaced apart from each other with respect to the gate structure interposed therebetween, on the semiconductor layer, wherein the semiconductor layer having an upper layer whose thickness is increased toward a first direction facing the drain electrode from the gate structure.

The upper layer has a top surface with a step shape whose height is increased toward the first direction.

The semiconductor device further includes an oxide film interposed between the upper layer and the gate structure, the oxide film covering the recess structure in a conformal manner.

The gate structure has a bottom surface with a step shape whose height is increased toward the first direction.

The gate structure includes: a gate electrode for blocking a current flow between the source electrode and the drain electrode; and a field plate extended toward the drain electrode from the gate electrode.

The gate structure has a bottom surface with a step shape including two or more step differences.

In accordance with still another aspect of the present invention to achieve the object, there is provided a semiconductor device including: a base substrate; a semiconductor layer which is disposed on the base substrate and has a 2DEG formed therewithin; a gate structure on the semiconductor layer; and a source electrode and a drain electrode which are disposed to be spaced apart from each other with respect to the gate structure interposed therebetween, wherein the semiconductor layer has an upper layer whose thickness is increased toward a first direction facing the drain electrode so that the 2DEG has a concentration increased toward the first direction facing the drain electrode.

The gate structure includes: a gate electrode; and a field plate extended toward the drain electrode from the gate electrode.

The semiconductor layer comprises: a lower layer disposed on the base substrate; and an upper layer disposed on the lower layer, wherein the upper layer includes: a first recess exposing the lower layer; and a second recess which is connected to the first recess and has a bottom surface with a height higher than that of the first recess.

In accordance with still another aspect of the present invention to achieve the object, there is provided a method for manufacturing a semiconductor device including the steps of: preparing a base substrate; forming a semiconductor layer having a top surface with a step shape whose height is increased toward a first direction, on the base substrate; forming a gate structure having a bottom surface with a shape corresponding to that of the top surface, on the semiconductor layer; and forming a source electrode and a drain electrode which are disposed to be spaced apart from with respect to the gate structure interposed therebetween, on the semiconductor layer, wherein the first direction faces the drain electrode.

The method further includes a step of forming an oxide film which covers the recess structure in a conformal manner, before the step of forming the gate structure.

The step of forming the semiconductor layer includes the steps of: forming a lower layer on the base substrate; forming an upper layer having an energy band gap higher than that of the lower layer, on the lower layer; and forming a recess structure having a bottom surface whose height is increased toward the first direction, on the upper layer.

The step of forming the recess structure includes the steps of: forming a first recess exposing the lower layer, on the upper layer; and forming a second recess which is connected to the first recess and has a step difference higher than the height of the bottom surface of the first recess.

One part of the gate structure disposed on the first recess is used to block a current flow between the source and drain electrodes, and the other part of the gate structure disposed on the second recess is sued as a field plate which distributes an electric field of the gate electrode and the drain electrode.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a plane-view showing a semiconductor device in accordance with an embodiment of the present invention;

FIG. 2 is a cross-sectional view taken along a line I-I′ shown in FIG. 1; and

FIGS. 3 to 7 are views showing methods for manufacturing semiconductor devices in accordance with an embodiment of the present invention, respectively.

### DETAILED DESCRIPTION OF THE PREFERABLE EMBODIMENTS

The invention now will be described more fully hereinafter with reference to the accompanying drawings, in which exemplary embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Preferred embodiments of the invention will be described below with reference to cross-sectional views, which are exemplary drawings of the invention. The exemplary drawings may be modified by manufacturing techniques and/or tolerances. Accordingly, the preferred embodiments of the invention are not limited to specific configurations shown in the drawings, and include modifications based on the method of manufacturing the semiconductor device. For example, an etched region shown at a right angle may be formed in the rounded shape or formed to have a predetermined curvature. Therefore, regions shown in the drawings have schematic characteristics. In addition, the shapes of the regions shown in the drawings exemplify specific shapes of regions in an element, and do not limit the invention.

Hereinafter, a detailed description will be given of a semiconductor device and a method for manufacturing the same in accordance with embodiments of the present invention, with reference to accompanying drawings.

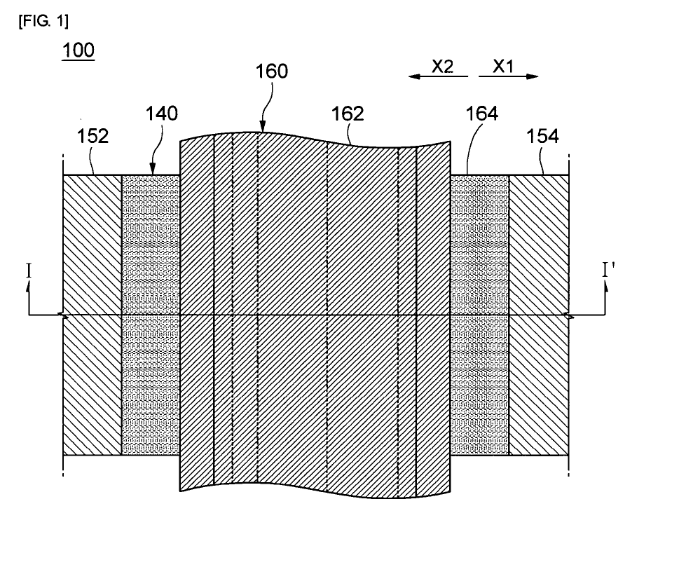

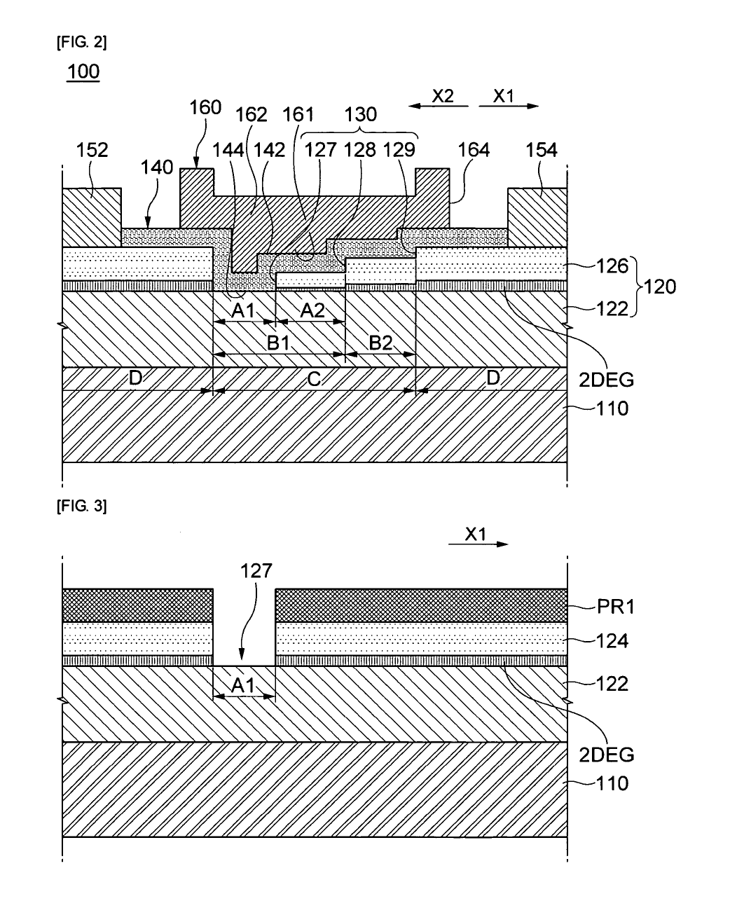

FIG. 1 is a plane-view showing a semiconductor device in accordance with one embodiment of the present invention, and FIG. 2 is a cross-sectional view taken along a line I-I′ of FIG. 1.

Referring to FIGS. 1 and 2, the semiconductor device 100 in accordance with one embodiment of the present invention may include a base substrate 110, a semiconductor layer 120, a source electrode 152, a drain electrode 154, and a gate structure 150.

The base substrate 110 may be a plate for formation of the semiconductor device having a high electron mobility transistor (HEMT) structure. For example, the base substrate 110 may be a semiconductor substrate. As for the base substrate 110, at least one of a silicon substrate, a silicon carbide substrate, and a sapphire substrate may be exemplified.

The semiconductor layer 120 may be disposed on the base substrate 110. For example, the semiconductor layer 120 may include a lower layer 122 and an upper layer 126 which are sequentially stacked on the base substrate 110. The upper layer 126 may be formed of a material having an energy band gap higher than that of the lower layer 122. In addition, the upper layer 126 may be formed of a material with a lattice parameter different from that of the lower layer 122. For example, the lower layer 122 and the upper layer 126 may be films which contain a III-nitride-based material. In particular, the lower layer 122 and the upper layer 126 may be formed of any one selected from among GaN, AlGaN, InGaN, and InAlGaN. For example, the lower layer 122 may be a gallium nitride film, and the upper layer 126 may be an aluminium gallium nitride film. In the semiconductor layer 120 with the above-described structure, a 2-Dimensional Electron Gas (2DEG) may be generated on the boundary of the lower layer 122 and the upper layer 126. When the semiconductor device 100 is operated, a current may flow through the 2DEG. Meanwhile, a buffering film (not shown) may be further provided between the base substrate 110 and the lower layer 122 so as to solve problems caused by lattice mismatch generated between the base substrate 110 and the lower layer 122.

Meanwhile, the upper layer 126 may have the recess structure 130 formed thereon. The recess structure 130 is a resulting material formed by etching the upper layer 126 between the source electrode 152 and the drain electrode 154. For example, the recess structure 130 may include first to third recesses 127 to 129. The first recess 127 may be a trench passing through a first region A1 of the upper layer 126 between the source electrode 152 and the drain electrode 154. The first recess 127 may expose the lower layer 122. The second recess 128 may be provided to be closer to the drain electrode 154 than the first recess 127. The second recess 128 is connected to the first recess 127, and may have a step height higher than that of the first recess 127. The third recess 129 is connected to the second recess 128 at a position closer than that of the drain electrode 154, and may have a step height higher than that of the second recess 128. Thus, the recess structure 130 may have a bottom surface with a step shape whose height is increased toward the third recess 129 from the first recess 127. Since the recess structure 130 is provided to have a step shape, the upper layer 126 may have a step-shaped top surface 126a whose height is gradually increased toward the drain electrode 154. In this case, the thickness of the upper layer 126 may get thick toward a first direction X1.

The semiconductor layer 120 having the same structure may have concentrations of the 2DEG which are different for each region. For example, the semiconductor layer 120 of a region B where no recess structure 130 is formed may include the upper layer 126 with relatively thick thickness. Thus, on the semiconductor layer 120 of a region D where no recess structure 130 is formed, a 2DEG having a high concentration may be formed. On the contrary, on the semiconductor layer 120 of a region where the recess structure 130 is formed, a 2DEG having a relatively lower concentration may be formed. In more particular, since the first recess 127 may be a trench which exposes the lower layer 122, the 2DEG may fail to be formed on the first region A1 of the semiconductor layer 120 on which the first recess 127 is formed. Also, a 2DEG having a concentration higher than that of the first region A1 may be formed on a region where the second recess 128 is formed. Thus, on the semiconductor layer 120, the 2DEG may be formed that lowers toward a second direction X2 facing the gate structure 160 from the drain electrode 154.

An insulating film may be further disposed between the semiconductor layer 120 and the gate structure 160. For example, an oxide film 140 may be further disposed between the semiconductor layer 120 and the gate structure 160. The oxide film 140 may be provided between the source electrode 152 and the drain electrode 154 to cover the recess structure 130 in a conformal manner. In this case, the oxide film 140 may have a shape corresponding to the step shape of the recess structure 130. Thus, the oxide film 140 may have a step-shaped top surface 142 whose height is increased toward the first direction X1. Meanwhile, the oxide film 140 may be a film composed of SiO2. Although the present embodiment has been illustrated taking an example where the insulating film interposed between the semiconductor layer 120 and the gate structure 160 may be an oxide film, the dielectric film may include a nitride film.

The source electrode 152 and the drain electrode 154 may be disposed to be spaced apart from each other with respect to the gate structure 160 interposed therebetween. The source electrode 152 and the drain electrode 154 may be disposed to be spaced apart from each other with respect to the gate structure 160 interposed therebetween. The source electrode 152 and the drain electrode 154 are bonded to the upper layer 126 to thereby come into ohmic contact with the upper layer 126.

The gate structure 160 may be disposed on the oxide film 140. The gate structure 160 is directly bonded to the oxide film 140 to thereby form a schottky electrode. The gate structure 160 may have a bottom surface 161 with a shape corresponding to the top surface 142 of the oxide film 140. Thus, the bottom surface 161 of the gate structure 160 may have a step shape increased toward the first direction X1. The gate structure 160 may include a gate electrode 162 disposed on the first recess 127 and a field plate 164 extended toward the drain electrode 154 from the gate electrode 162. To this end, the gate electrode 162 and the field plate 164 may be formed by performing the same etching process. The gate structure 160 may the gate electrode 162 and the field plate 164 formed of the same material. No boundary may be performed between the gate electrode 162 and the field plate 164.

Meanwhile, the source electrode 152, the drain electrode 154, and the gate structure 160 may be formed of various materials. For example, the source electrode 152 and the drain electrode 154 may be formed of the same material. The gate structure 160 may be formed of a metallic material different from that of the source electrode 152. In this case, the source electrode 152 and the drain electrode 154 may be formed of any one of metallic material of metal elements composed of Au, Ni, Pt, Ti, Al, Pd, Ir, Rh, Co, W, Mo, Ta, Cu, and Zn. The gate structure 160 may be formed of metallic material composed of metal elements different from any one of the above-described metal elements. Also, the source electrode 152, the drain electrode 154, and the gate structure 160 may be formed of the same metallic material. To this end, after same metal film is formed on the semiconductor layer 120, it is possible to simultaneously form the source electrode 152, the drain electrode 154, and the gate structure 160 through the same photoresist etching process.

As described above, the semiconductor device 100 may include the gate structure 160 which has a step-shaped bottom surface 161 whose height is increased toward the first direction X1. One side portion of the gate structure 160 may be used as the gate electrode 162 for blocking a current flow between the source electrode 152 and the drain electrode 154, and the other portion of the gate structure 160 may be used as the field plate 164, the other portion of the gate structure being close to the drain electrode 154. Thus, in the semiconductor device 100, it is possible to distribute an electric field concentrated on the gate electrode 162 and the drain electrode 154, thereby achieving high voltage operation. Further, it is possible to implement the HEMT structure in which device's characteristics are improved.

In the semiconductor device 100, the thickness of the upper layer 124 of the semiconductor layer 120 may be controlled so that the concentration of the 2DEG can be reduced toward the second direction X2 facing the gate electrode 162 from the drain electrode 154. In this case, it is possible to reduce a phenomenon where an electric field is concentrated on the gate electrode 162 and the drain electrode 154, so that the semiconductor device can perform a field plating function of distributing the electric field concentrated on the gate electrode 162 and the drain electrode 154, together with the field plate 164.

Also, in the semiconductor device 100, an insulating film (oxide film 140 in the present embodiment) is provided between the gate structure 150 and the semiconductor layer 120. Therefore, when no voltage is applied to the gate structure 150, there is achieved a normally off state where there is no current flow through the 2DEG even if a voltage is applied to the drain electrode 154. Thus, when the gage voltage is zero or on the minus side, the semiconductor device 100 may have the HEMT structure capable of performing an enhancement mode where there is no current flow.

Continuously, a description will be given of a method for manufacturing the semiconductor device in accordance with the embodiment of the present invention. Herein, the repeated description for the semiconductor device will be omitted or simplified.

FIGS. 3 to 7 are views showing methods for manufacturing the semiconductor device, respectively.

Referring to FIG. 3, the base substrate 110 may be prepared. As for the base substrate 110, the semiconductor substrate may be prepared. The step of preparing the base substrate 110 may include a step of preparing at least one of a silicon substrate, a silicon carbide substrate, and a sapphire substrate.

On the semiconductor layer 110, the lower layer 122 and a first nitride film 124 may be sequentially formed. For example, the step of forming the semiconductor layer 120 may be achieved by epitaxial-growing the lower layer 122 by using the base substrate 110 as a seed layer, and then epitaxial-growing the first nitride film 124 by using the epitaxial-grown the lower layer 122 as a seed layer. For example, the lower layer 122 may be a GaN film, and the first nitride film 124 may be an AlGaN film. As for an epitaxial growth process for forming the lower layer 122 and the first nitride film 124, at least one of a molecular beam epitaxial growth process, an atomic layer epitaxial growth process, a flow modulation organometallic vapor phase epitaxial growth process, a flow modulation organometallic vapor phase epitaxial growth process, and a hybrid vapor phase epitaxial growth process may be used. Furthermore, as for another process for forming the lower layer 122 and the first nitride film 124, any one of a chemical vapor deposition process and a physical vapor deposition process may be used.

After forming the first photoresist PR1, exposing the first region A1 of the first nitride film 124, on the first nitride film 124, the first etching process may be performed that uses the first photoresist pattern PR1 as an etching mask. Thus, on the first nitride film 124 of the first region A1, the first recess 127 may be formed that exposes the lower layer 122.

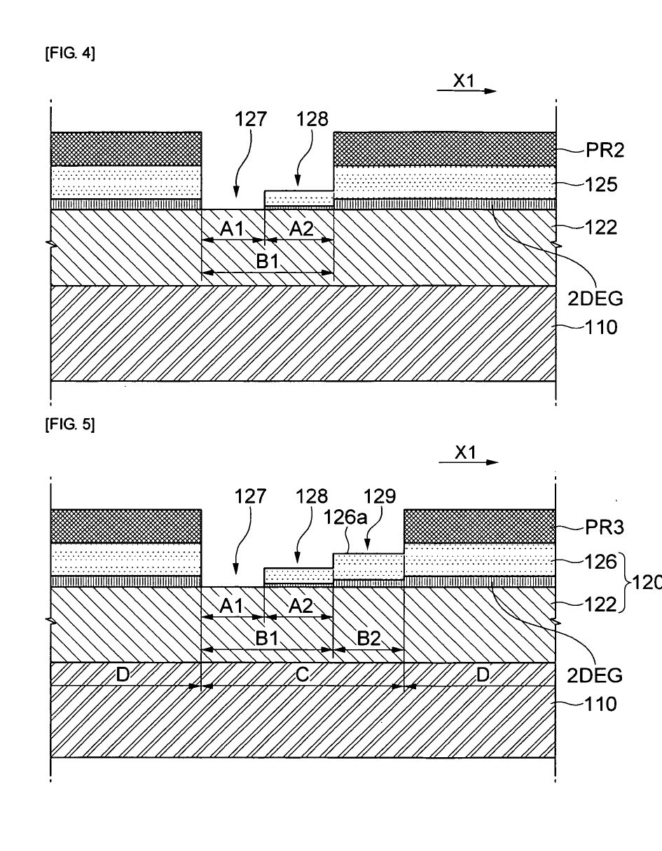

Referring to FIG. 4, the second nitride film 125 may be formed that has the second recess 128. For example, after forming the second photoresist pattern PR2, exposing the second region B1, on the first nitride film 124, indicated by reference numeral 124 of the FIG. 3A, the second etching process may be performed that uses the second photoresist pattern PR2 as an etching mask. Herein, the second region B1 may be a region which includes the first region A1, and a region A2 extended toward the first direction X1 from the first region A1 at a predetermined distance. Also, an etching speed of the second etching process may be controlled so that the lower layer 122 may fail to be exposed. Thus, on the lower layer 122, the first recess 127 exposing the lower layer 122, and the second nitride film 125 having the second recess 128 formed thereon to fail to expose the lower layer 122 may be formed. The second recess 128 has a bottom surface with a height higher than that of a bottom surface of the first recess 127 (e.g., height of the top surface of the lower layer 122). Thus, the first recess 127 and the second recess 128 may be formed to be in one step shape.

Referring to FIG. 5, the third recess 129 is formed on the second nitride film, indicated by reference numeral 125 of FIG. 3B, to thereby completely form the upper layer 126 of the semiconductor layer 120. For example, after the third photoresist pattern PR3 exposing the third region C is formed on the second nitride film 125, the third etching process may be performed that uses the third photoresist pattern PR3 as an etching mask. Herein, the third region C may be a region which includes the second region B1, and a region B2 extended toward the first direction X1 from the second region B1 at a predetermined distance. Also, an etching speed of the third etching process may be controlled so that the third recess 129 has a bottom surface with a height higher than that of the second recess 128. Thus, the recess structure 130 composed of the first to third recesses 127 to 129 formed thereon may be formed on the upper layer 126. Herein, the bottom surface of the recess structure 130 may have a shape increased toward the first direction X1. Thus, the top surface 126a with a step shape whose height is increased toward the first direction X1 may be formed on the upper layer 126 of the third region C.

Meanwhile, a 2DEG having different concentrations for each region may be formed on a boundary between the lower layer 122 and the upper layer 126. For example, the upper layer 126 having a relatively thick thickness may be formed on the semiconductor layer 120 of a region where no recess structure 130 is formed. Thus, on the semiconductor layer 120 of a region D where no recess structure 130 is formed, the 2DEG having a high concentration may be formed. On the contrary, since the first recess 127 is a trench exposing the lower layer 122, a 2DEG may fail to be formed on the semiconductor layer 120 of the first region A1. Also, a 2DEG having a higher concentration than that of the first region A1 may be formed on the region A2 where the second recess 128 is formed. A 2DEG having a higher concentration than that of the region A2 may be formed on the region B2 where the third recess 129 is formed. Thus, on the semiconductor layer 120, a 2DEG may be formed that has a concentration lowering toward the second direction X2 facing the gate structure 160 from the drain electrode 154.

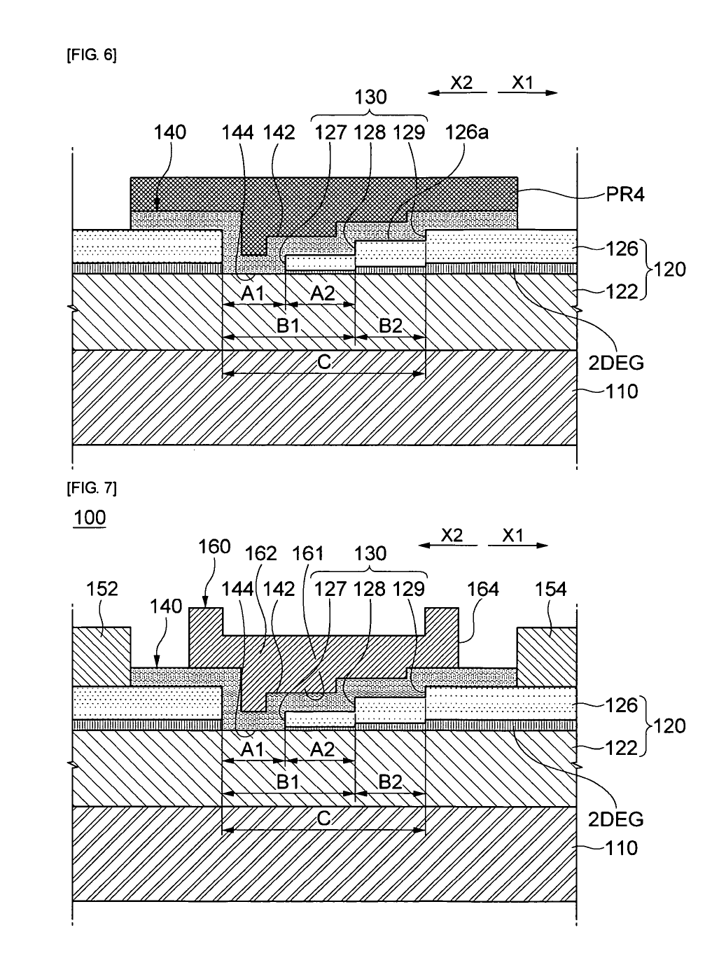

Referring to FIG. 6, on the semiconductor layer 120, the oxide film 140 may be formed. For example, an insulating film may be formed on the semiconductor layer 120 in a conformal manner. As for the insulating film, SiO2 film may be exemplified. The fourth photoresist pattern PR4 may be formed on the insulating film, and then the fourth photoresist pattern PR4 is used as an etching mask, thereby etching the insulating film. In this case, the fourth photoresist pattern PR4 may expose edge regions of both sides of the insulating film. Thus, the recess structure 130 covers the semiconductor layer 120 in a conformal manner, thereby forming the oxide film 140 having the top surface 142 with a step shape increased toward the first direction X1. In addition, the oxide film 140 may have a bonding surface 144 bonded to the lower layer 122.

Referring to FIG. 7, the source electrode 152 and the drain electrode 154 may be formed. For example, the first metal film may be formed on the semiconductor layer 120, and then a photoresist etching process is performed, thereby forming the source electrode 152 and the drain electrode 154 disposed to be spaced apart from each other with respect to the recess structure 130 interposed therewithin. The step of forming the first metal film may include a step of forming a metal film, including at least one of Au, Ni, Pt, Ti, Al, Pd, Ir, Rh, Co, W, Mo, Ta, Cu, and Zn, on the upper layer 124 in a conformal manner.

Thereafter, the gate structure 160 may be formed. For example, the step of forming the gate structure 160 may be achieved by forming the second metal film of a material different from that of the first metal film on a resulting material formed with the oxide film 140, and then performing a photoresist etching process. Since the second metal film is provided to cover the oxide film 140 with the step-shaped top surface 142, the bottom surface of the gate structure 160 may be provided to have a step shape whose height is increased toward the first direction X1. The gate structure 160 may include the gate electrode 152 disposed on the top part of the first region A1 where the first recess is formed, and a field plate 164 extended toward the first direction X1 from the source electrode 152.

As described above, through the method for manufacturing the semiconductor device, it is possible to manufacture a semiconductor device which is provided with the gate structure 160 with a step shape whose height is increased toward the first direction X1 facing the drain electrode 154. In this case, a part of the gate structure 160 extended toward the drain electrode 154 can perform a field plating function of distributing an electric field concentrated on the gate electrode 162 and the drain electrode 154.

In addition, since a 2DEG has a concentration decreased toward the second direction X2 facing the gate structure 160, the semiconductor device 100 can distribute an electric field concentrated on the gate electrode and the drain electrode. Thus, by the method for manufacturing the semiconductor device, it is possible to operate the semiconductor device at a high voltage. Further, it is possible to manufacture the semiconductor device 100 in which device's characteristics due to electric field concentration can be prevented.

The semiconductor device in accordance with the present invention is provided with a gate structure with a step shape whose height is increased toward a first direction facing a drain electrode. The gate structure is provided with a gate electrode, and a field plate which distributes an electric field concentrated on the gate and drain electrodes, thereby preventing reduction of device's characteristics due to the electric field concentration.

In the semiconductor device in accordance with the present invention, a concentration of a 2DEG is reduced toward a second direction facing the gate electrode, thereby distributing an electric field concentrated on the gate and drain electrodes.

Thus, in the semiconductor device, it is possible to implement a high-voltage operation, and to prevent reduction in device's characteristics due to electric field concentration.

In a method for manufacturing the semiconductor device, it is possible to manufacture a semiconductor device which is provided with a gate structure having a step shape whose height is increased toward a first direction facing the drain electrode. Thus, by the method for manufacturing the semiconductor device of the present invention, it is possible to manufacture a semiconductor device in which high-voltage operation is achieved and reduction of device's characteristics due to electric field concentration is prevented.

In the method for manufacturing the semiconductor device of the present invention, it is possible to reduce a concentration of a 2DEG toward a second direction facing the gate electrode, thereby manufacturing a semiconductor device which distributes an electric field concentrated on the gate and drain electrodes. Thus, it is possible to operate the semiconductor device at a high voltage, and to manufacture a semiconductor device in which reduction of device's characteristics due to electric field concentration is prevented.

As described above, although the preferable embodiments of the present invention have been shown and described, it will be appreciated by those skilled in the art that substitutions, modifications and variations may be made in these embodiments without departing from the principles and spirit of the general inventive concept, the scope of which is defined in the appended claims and their equivalents.

1. A semiconductor device comprising:
a base substrate;
a semiconductor layer which is disposed on the base substrate and has a recess structure formed thereon;
a gate structure covering the recess structure;
a source electrode and a drain electrode which are disposed to be spaced apart from each other with respect to the gate structure interposed therebetween, on the semiconductor layer,
wherein the semiconductor layer having an upper layer whose thickness is increased toward a first direction facing the drain electrode from the gate structure.

2. The semiconductor device of claim 1, wherein the upper layer has a top surface with a step shape whose height is increased toward the first direction.

3. The semiconductor device of claim 1, further comprising an oxide film interposed between the upper layer and the gate structure, the oxide film covering the recess structure in a conformal manner.

4. The semiconductor device of claim 1, wherein the gate structure has a bottom surface with a step shape whose height is increased toward the first direction.

5. The semiconductor device of claim 4, wherein the gate structure comprises:
a gate electrode for blocking a current flow between the source electrode and the drain electrode; and
a field plate extended toward the drain electrode from the gate electrode.

6. The semiconductor device of claim 4, wherein the gate structure has a bottom surface with a step shape including two or more step differences.

7. A semiconductor device comprising:
a base substrate;
a semiconductor layer which is disposed on the base substrate and has a 2DEG formed therewithin;
a gate structure on the semiconductor layer; and
a source electrode and a drain electrode which are disposed to be spaced apart from each other with respect to the gate structure interposed therebetween,
wherein the semiconductor layer has an upper layer whose thickness is increased toward a first direction facing the drain electrode so that the 2DEG has a concentration increased toward the first direction facing the drain electrode.

8. The semiconductor device of claim 7, wherein the gate structure comprises:
a gate electrode; and
a field plate extended toward the drain electrode from the gate electrode.

9. The semiconductor device of claim 7, wherein the semiconductor layer comprises:
a lower layer disposed on the base substrate; and
an upper layer disposed on the lower layer,
wherein the upper layer comprises:
a first recess exposing the lower layer; and
a second recess which is connected to the first recess and has a bottom surface with a height higher than that of the first recess.

10. A method for manufacturing a semiconductor device comprising:
preparing a base substrate;
forming a semiconductor layer having a top surface with a step shape whose height is increased toward a first direction, on the base substrate;
forming a gate structure having a bottom surface with a shape corresponding to that of the top surface, on the semiconductor layer; and
forming a source electrode and a drain electrode which are disposed to be spaced apart from with respect to the gate structure interposed therebetween, on the semiconductor layer,
wherein the first direction faces the drain electrode.

11. The method of claim 10, wherein, before forming the gate structure, further comprises forming an oxide film which covers the recess structure in a conformal manner.

12. The method of claim 10, wherein forming the semiconductor layer comprises:
forming a lower layer on the base substrate;
forming an upper layer having an energy band gap higher than that of the lower layer, on the lower layer; and
forming a recess structure having a bottom surface whose height is increased toward the first direction, on the upper layer.

13. The method of claim 12, wherein forming the recess structure comprises:
forming a first recess exposing the lower layer, on the upper layer; and
forming a second recess which is connected to the first recess and has a step difference higher than the height of the bottom surface of the first recess.

14. The method of claim 13, wherein one part of the gate structure disposed on the first recess is used to block a current flow between the source and drain electrodes, and the other part of the gate structure disposed on the second recess is sued as a field plate which distributes an electric field of the gate electrode and the drain electrode.

15. The semiconductor device of claim 3, wherein the gate structure has a bottom surface with a step shape whose height is increased toward the first direction.

16. The semiconductor device of claim 15, wherein the gate structure comprises:
a gate electrode for blocking a current flow between the source electrode and the drain electrode; and
a field plate extended toward the drain electrode from the gate electrode.

17. The semiconductor device of claim 15, wherein the gate structure has a bottom surface with a step shape including two or more step differences.
